(19) United States
(12) Patent Application Publication
(10) Pub. No.: US 2019/0139987 A1
(43) Pub. Date: May 9, 2019

(54) PIXEL UNIT, ARRAY SUBSTRATE AND DISPLAY PANEL

(71) Applicant: Shenzhen China Star Optoelectronics Semiconductor Display Technology Co., Ltd., Shenzhen, Guangdong (CN)

(72) Inventor: Qiming Gan, Shenzhen (CN)

(21) Appl. No.: 15/749,403

(22) PCT Filed: Dec. 21, 2017
(86) PCT No.: PCT/CN2017/117680

§ 371 Date: Jan. 31, 2018

(30) Foreign Application Priority Data
Nov. 7, 2017 (CN) 201711097719.1

(51) Int. Cl. H01L 27/12; G02F 1/1362; G02F 1/1337; H01L 23/31

(52) U.S. Cl. CPC H01L 27/124; G02F 1/136227; G02F 1/133707; G02F 2201/123; G02F 1/133753; H01L 23/3171; G02F 1/136286

(57) ABSTRACT

The present disclosure provides a pixel unit, an array substrate and a display panel. The pixel unit includes a main pixel portion and a secondary pixel portion electrically connected to the main pixel portion, wherein the main pixel portion includes a first horizontal trunk, a first vertical trunk and first branches; the secondary pixel portion includes a second horizontal trunk, a second vertical trunk and second branches; wherein, an acute angle between the first branches and the first horizontal trunk is different from an acute angle between the second branches and the second horizontal trunk. The implementation of the present disclosure may make the liquid crystal molecules in a pixel unit to have different inclination angle so as to improve the side viewing of the display panel.

### TECHNICAL FIELD

The present disclosure generally relates to the display field, and in particular to a pixel unit, an array substrate and a display panel.

### BACKGROUND

With the development of optoelectronic and semiconductor technologies, the flat screen has been widely used. Compared with other flat screens, the liquid crystal display has several advantages such as high space utilization, low consumption, no radiation and low electromagnetic interference. Nowadays, the market demands for the performance of the LCD include high contrast, fast response and wide viewing filed. In order to provide a wide viewing filed, various technologies may be utilized such as multi-domain vertical alignment (MVA), multi-domain horizontal alignment (MHA), twisted nematic plus wide viewing film (TN+film) and in-plane switching (IPS).

Although the above-mentioned technologies may enlarge the viewing field, the problem of color washout cannot be ignored, especially for the large-size LCD panel.

### SUMMARY

The present disclosure provides a pixel unit, an array substrate and a display panel to reduce the color washout of the display panel so as to improve its side viewing.

To solve the above mentioned problem, a technical scheme adopted by the present disclosure is to provide an array substrate. The array substrate includes a plurality of scan lines and a plurality of data lines perpendicularly crossing the plurality of scan lines, wherein, the plurality of scan lines and the plurality of data lines cooperatively define a plurality of pixel units, each of the plurality of pixel units includes a main pixel portion and a secondary pixel portion electrically connected to the main pixel portion, wherein the main pixel portion includes a first horizontal trunk, a first vertical trunk and first branches, the first vertical trunk is substantially perpendicular to and intersected with the first horizontal trunk, the first branches extend outward from the first horizontal trunk and the first vertical trunk and located in a pixel domain defined by the first horizontal trunk and the first vertical trunk; the secondary pixel portion includes a second horizontal trunk, a second vertical trunk and second branches, the second vertical trunk is substantially perpendicular to and intersected with the second horizontal trunk, the second branches extend outward from the second horizontal trunk and the second vertical trunk and located in a pixel domain defined by the second horizontal trunk and the second vertical trunk; wherein, an acute angle between the first branches and the first horizontal trunk is different from an acute angle between the second branches and the second horizontal trunk; each of the plurality of pixel units further includes a thin film transistor, wherein a gate electrode of the thin film transistor is connected to a scan line, a source electrode of the thin film transistor is connected to a data line, and a drain electrode of the thin film transistor is connected to the main pixel portion and the secondary pixel portion; a ratio of an area of the main pixel portion to an area of the secondary pixel portion is between 3/7 and 7/3.

To solve the above mentioned problem, another technical scheme adopted by the present disclosure is to provide a pixel unit. The pixel unit includes a main pixel portion and a secondary pixel portion electrically connected to the main pixel portion, wherein the main pixel portion includes a first horizontal trunk, a first vertical trunk and first branches, the first vertical trunk is substantially perpendicular to and intersected with the first horizontal trunk, the first branches extend outward from the first horizontal trunk and the first vertical trunk and located in a pixel domain defined by the first horizontal trunk and the first vertical trunk; the secondary pixel portion includes a second horizontal trunk, a second vertical trunk and second branches, the second vertical trunk is substantially perpendicular to and intersected with the second horizontal trunk, the second branches extend outward from the second horizontal trunk and the second vertical trunk and located in a pixel domain defined by the second horizontal trunk and the second vertical trunk; wherein, an acute angle between the first branches and the first horizontal trunk is different from an acute angle between the second branches and the second horizontal trunk.

To solve the above mentioned problem, another technical scheme adopted by the present disclosure is to provide a display panel. The display panel includes a array substrate, an opposite substrate arranged opposite to the array substrate and a liquid crystal layer therebetween; the array substrate including a plurality of scan lines and a plurality of data lines perpendicularly crossing the plurality of scan lines, wherein the plurality of scan lines and the plurality of data lines cooperatively define a plurality of pixel units, each of the plurality of pixel units includes a main pixel portion and a secondary pixel portion electrically connected to the main pixel portion; the main pixel portion includes a first horizontal trunk, a first vertical trunk and first branches, the first vertical trunk is substantially perpendicular to and intersected with the first horizontal trunk, the first branches extend outward from the first horizontal trunk and the first vertical trunk and located in a pixel domain defined by the first horizontal trunk and the first vertical trunk; the secondary pixel portion includes a second horizontal trunk, a second vertical trunk and second branches, the second vertical trunk is substantially perpendicular to and intersected with the second horizontal trunk, the second branches extend outward from the second horizontal trunk and the second vertical trunk and located in a pixel domain defined by the second horizontal trunk and the second vertical trunk; an acute angle between the first branches and the first horizontal trunk is different from an acute angle between the second branches and the second horizontal trunk; the main pixel portion and the secondary pixel portion is electrically connected via an indium tin oxide structure of an array substrate.

The pixel unit, the array substrate and the display panel disclosed by the present disclosure may all include a main pixel portion and a secondary pixel portion electrically connected to the main pixel portion. The main pixel portion includes a first horizontal trunk, a first vertical trunk and first branches. The first vertical trunk is substantially perpendicular to and intersected with the first horizontal trunk. The first branches extend outward from the first horizontal trunk and the first vertical trunk, and located in a pixel domain defined by the first horizontal trunk and the first vertical trunk. The secondary pixel portion includes a second horizontal trunk, a second vertical trunk and second branches. The second vertical trunk is substantially perpendicular to and intersected with the second horizontal trunk. The second branches extend outward from the second horizontal trunk and the second vertical trunk, and located in a pixel domain defined by the second horizontal trunk and the second vertical trunk. An acute angle between the first branches and the first horizontal trunk is different from an acute angle between the second branches and the second horizontal trunk. The implementation of the present disclosure may make the liquid crystal molecules in a pixel unit to have different inclination direction so as to improve the side viewing of the display panel.

### BRIEF DESCRIPTION OF THE DRAWINGS

FIG. 1 is a schematic diagram of a pixel unit according to an embodiment of the present disclosure.

FIG. 2 is an enlarged view of the main pixel portion and the secondary pixel portion shown in FIG. 1.

FIG. 3 is a section view of the pixel electrode and the thin film transistor shown in FIG. 1.

FIG. 4 is another section view of the pixel electrode and the thin film transistor shown in FIG. 1.

FIG. 5 is a schematic diagram of an array substrate according to an embodiment of the present disclosure.

FIG. 6 is a schematic diagram of a display panel according to an embodiment of the present disclosure.

### DETAILED DESCRIPTION

The terms “first” and “second” in the present disclosure are merely for illustrative purposes, and should not be construed as indicating or implying the relative importance or the number of indicated technical features. Thus, features defined with “first” and “second” may explicitly or implicitly include at least one of the features. In the description of the present disclosure, “a plurality of” or “multiple” means at least two, for example, two, three, etc., unless expressly limited. Moreover, the terms of “include”, “have” and any variations thereof are intended to encompass the items listed thereafter and equivalents thereof as well as additional items. For example, a process, a method, a system, a product or a device that includes a series of steps or components is not limited to these steps or components already listed, but many optional steps or components not listed.

Hereinafter, an exemplary embodiment of the present disclosure will be described with reference to the accompanying drawings. Well-known functions and structures will not be described in detail for brevity and clarity. The terms utilized in the description should be explained on the basis of the entire disclosure of the specification.

Briefly, the present disclosure relates to a pixel unit, an array substrate and a display panel. The pixel unit may be divided in to two portions connected with each other and having a pozidriv pattern. The angles between the branches and the trunk of the two portions of the pixel electrode are set to be different such that the side viewing of the pixel may be improved.

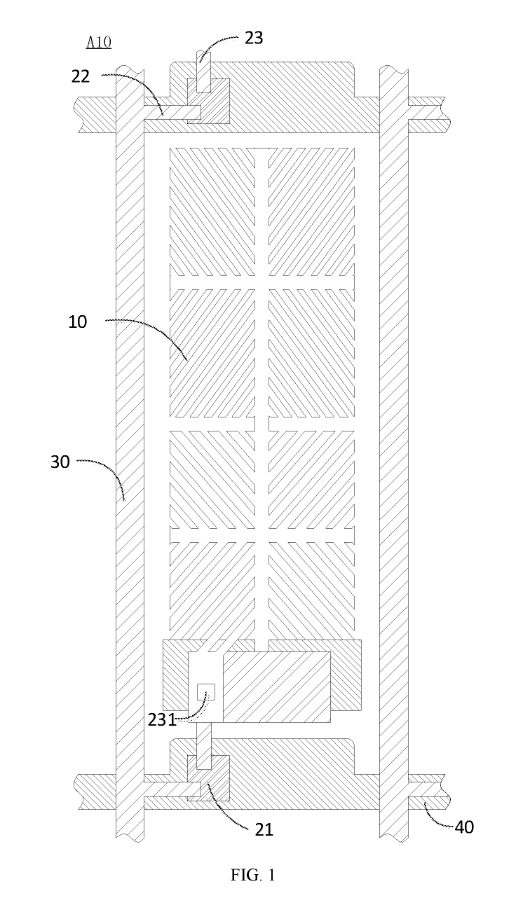

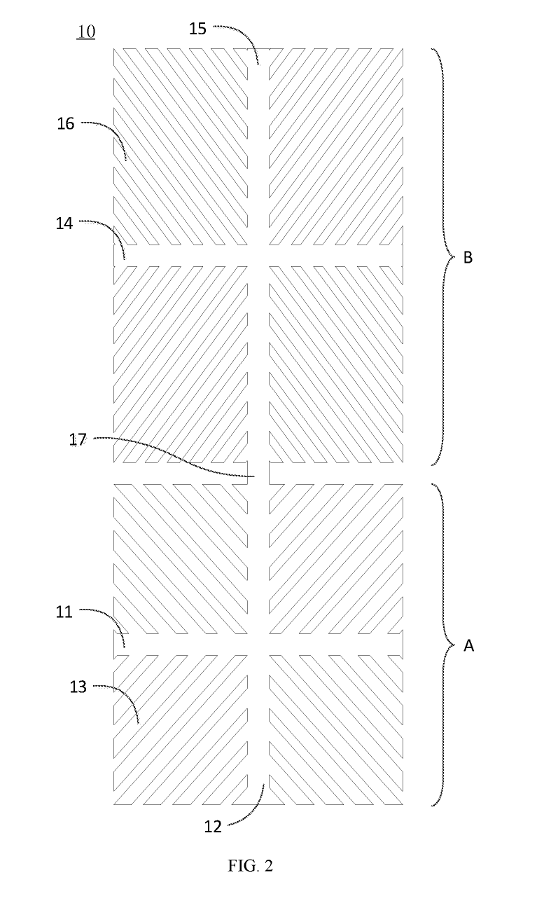

Referring to FIGS. 1-2, FIG. 1 is a schematic diagram of a pixel unit according to an embodiment of the present disclosure, and FIG. 2 is an enlarged view of the main pixel portion and the secondary pixel portion shown in FIG. 1.

As shown in FIGS. 1-2, the pixel unit A10 may include a main pixel portion A and a secondary pixel portion B electrically connected to the main pixel portion A. In one embodiment, the main pixel portion A may be electrically connected to the secondary pixel portion B by an indium tin oxide (ITO) structure 17.

The main pixel portion A may include a first horizontal trunk 11, a first vertical trunk 12 and first branches 13. The first horizontal trunk 11 may be substantially perpendicular to and intersected with the first vertical trunk 12. The first branches 13 may extend outward from the first horizontal trunk 11 and the first vertical trunk 12, and be located in a pixel domain defined by the first horizontal trunk 11 and the first vertical trunk 12.

It should be understood that the first horizontal trunk 11 and the first vertical trunk 12 may divide the main pixel portion A into four sub-domains having the same area. The first branches 13 may be symmetric about the first horizontal trunk 11 and the first vertical trunk 12. In each sub-domain, the first branches 13 may be spaced from each other. The acute angle between the first horizontal trunk 11 and each of the branches 13 may be identical.

The secondary pixel portion B may include a second horizontal trunk 14, a second vertical trunk 15 and second branches 16. The second horizontal trunk 14 may be substantially perpendicular to and intersected with the second vertical trunk 15. The second branches 16 may extend outward from the second horizontal trunk 14 and the second vertical trunk 15, and located in a pixel domain defined by the second horizontal trunk 14 and the second vertical trunk 15.

It should be understood that the second horizontal trunk 14 and the second vertical trunk 15 may divide the secondary pixel portion into four sub-domains having the same area. The second branches 16 may be symmetric about the second horizontal trunk 14 and the second vertical trunk 15. In each the sub-domain, the second branches 16 may be spaced from each other. The acute angle between the second horizontal trunk 14 and each of the branches 13 may be identical.

It should be understood that the first horizontal trunk 11 and the second horizontal trunk 14 may both have a strip configuration of same size. The first vertical trunk 12 and the second vertical trunk 15 may both have a strip configuration of same size or different sizes. The first branches 13 and the second branches 16 may also have a strip configuration.

In one embodiment, the acute angle between the first branches 13 and the first horizontal trunk 11 is different from the acute angle between the second branches 16 and the second horizontal trunk 14.

Specifically, the acute angle between the first branches 13 and the first horizontal trunk 11 may be 45 degree. The acute angle between the second branches 14 and the second horizontal trunk 15 may be no less than 15 degree and no more than 40 degree, or the acute angle between the second branches 14 and the second horizontal trunk 15 is no less than 50 degree and no more than 75 degree. Optionally, the acute angle between the second branches 16 and the second horizontal trunk 14 may be 30 degree or 60 degree. In this embodiment, 60 degree is selected.

In one embodiment, the main pixel portion A and the secondary pixel portion B may have a rectangle configuration. The length and the width of the main pixel portion A may be between 2 μm and 5 μm. The length and the width of the secondary pixel portion B may be between 2 μm and 5 μm. In this embodiment, the lengths of the main pixel portion A and the secondary pixel portion B may be set to 3.5 The widths of the main pixel portion A and the secondary pixel portion B may be set to 2.5 μm.

In one embodiment, the ratio of the area of the main pixel portion A to the area of the secondary pixel portion B may be between 3/7 and 7/3 (including 3/7 and 7/3). Optionally, the ratio may be set to 4/6. In this embodiment, the ratio of the area of the main pixel portion A to the area of the secondary pixel portion B may be set to 5/5.

In one embodiment, the main pixel portion A and the secondary pixel portion B may be arranged to correspond to pixels with the same color or different colors (for example, a red pixel and a green pixel, a green pixel and a blue pixel, a blue pixel and a red pixel), or to a single pixel (for example, a red pixel, a green pixel or a blue pixel).

The pixel unit A10 may further include a thin film transistor 20. A gate electrode 21 of the thin film transistor 20 may be connected to a scan line 40. A source electrode 22 of the thin film transistor 20 may be connected to a data line 30. A drain electrode 23 of the thin film transistor 20 may be connected to the pixel electrode 10. In this embodiment, the main pixel portion A and the second pixel portion B cooperatively consist the pixel electrode 10.

In one embodiment, the pixel electrode 10 of the pixel unit A10 may be made of the indium tin oxide.

In one embodiment, the gate electrode 21, the source electrode 22 and the drain electrode 23 may consist the thin film transistor 20.

Specifically, a through-hole 231 may be defined to expose the drain electrode 23 of the thin film transistor 20. The pixel electrode 10 may be electrically connected to the drain electrode 23 through the through-hole 231.

It should be noticed that the pixel electrode 10 may be controlled only by one thin film transistor 20.
Specifically, when powered on, the gate electrode 21 of the thin film transistor may receive a breakover voltage. The current may reach the source electrode 22 from the data line 30, and then reach the drain 23 through the channel layer. Finally the current may pass through the through-hole 231 to charge the pixel electrode 10.

When the pixel unit A10 is charged, the liquid crystal molecules may begin to incline along the direction of the branches. Since the directions of the branches of the main pixel portion A and the secondary pixel portion B are different, the inclination direction of the liquid crystal molecules corresponding to the main pixel portion A may differ from that corresponding to the secondary pixel portion B. Therefore, the isotropy of light transmittance of the liquid crystal layer may be improved as well as the viewing filed of the liquid crystal screen, and the problem of color washout may be reduced or avoided. Moreover, compared with the 8-domain pixel electrode utilizing 3 thin film transistors, the 8-domain pixel electrode of the present disclosure may utilize only one thin film transistor for control. Thus, the aperture ratio of the pixels may be augmented. For the 8-domain pixel electrode utilizing 3 thin film transistors, it is quite difficult to balance the voltage between the main pixel portion A and the secondary portion B. However, for the pixel electrode of the present disclosure, this step is no longer necessary.

Referring to FIG. 3, FIG. 3 is a section view of the pixel electrode and the thin film transistor shown in FIG. 1.

The pixel unit A10 may include a substrate 26, a thin film transistor 20 arranged on the substrate 26, a passivation layer 25a arranged on the thin film transistor 20 and the substrate 26, and a pixel electrode 10a arranged on the passivation layer 25a. The thin film transistor 20 is not shown except for the drain electrode 23.

In one embodiment, the substrate may be made of transparent glass or plastic. The passivation layer may be made of silicon nitride or silicon oxide. The pixel electrode may be made of transparent indium tin oxide. In this embodiment, the substrate may be made of transparent glass. The passivation layer may be made of silicon nitride. The pixel electrode may be made of transparent indium tin oxide.

The passivation layer 25a may be planar. The pixel electrode 10a may have a uniform thickness and cover the planar passivation layer 25a.

Specifically, the passivation layer 25a may define a through-hole 231a corresponding to the location of the drain electrode 23. The pixel electrode 10a may be electrically connected to the drain electrode 23 of the thin film transistor through the through-hole 231a.

Specifically, after the passivation layer 25a with the through-hole 231a is formed by etching via a photo mask, an indium tin oxide layer may be formed on the passivation layer 25a. By etching via another photo mask, the pattern of the pixel electrode 10 shown as FIG. 2 may be formed.

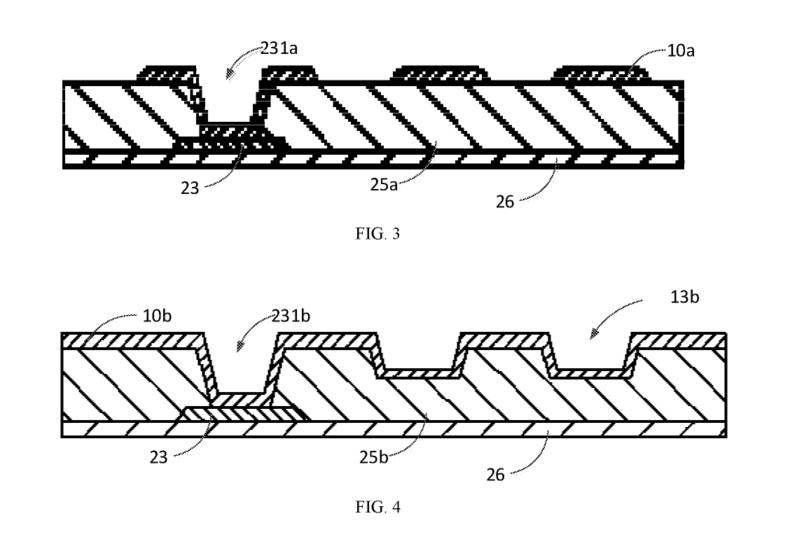

Referring to FIG. 4, FIG. 4 is another section view of the pixel electrode and the thin film transistor shown in FIG. 1.

The pixel unit A10 may include a substrate 26, a thin film transistor 20 arranged on the substrate 26, a passivation layer 25b arranged on the thin film transistor 20 and the substrate 26, and a pixel electrode 10b arranged on the passivation layer 25b. The thin film transistor 20 is not shown except for the drain electrode 23.

In one embodiment, the passivation layer 25b may be patterned. Different portions of the passivation layer 25b which correspond to multiple pixel electrodes 10 may be patterned with a same pattern as the pattern of the pixel electrode shown in FIG. 2. The pixel electrode 10b may have a uniform thickness and cover the whole surface of the passivation layer 25b such that the pixel electrode 10b may have the same pattern as the passivation layer 25b.

Specifically, as shown in FIG. 2, for each of the pixel unit A10, the patterned passivation layer 25b may be divided into 8 domains. Each of the pixel unit corresponding to the patterned passivation layer 25b may include the main pixel portion and the secondary pixel portion. Each of the main pixel portion and the secondary pixel portion may include a horizontal trunk, a vertical trunk substantially perpendicular to the horizontal trunk, and branches arranged to be symmetric about the horizontal trunk and the vertical trunk. In one embodiment, the acute angle between the branches and the horizontal trunk of the main portion may differ from the acute angle between the branches and the horizontal trunk of the secondary portion.

Specifically, the passivation layer 25b may define a through-hole 231b corresponding to the location of the drain electrode 23 of the thin film transistor 20. The pixel electrode 10b may be electrically connected to the drain electrode 23 of the thin film transistor 20 through the through-hole 231a.

Specifically, the through-hole 231b and the slit 13b (16b) may be made by a photolithography process via a gray tone mask (GTM).

Referring to FIG. 5, FIG. 5 is a schematic diagram of an array substrate according to an embodiment of the present disclosure.

The array substrate 100 may include multiple pixel units A10, multiple scan lines (G21, G22, G23, G24 . . . ) and multiple data lines (D21, D22, D23, D24, D25 . . . ).

In one embodiment, the main portion A and the secondary portion B of the pixel unit A10 may also be arranged side-by-side.

The thin film transistor 20 of the pixel unit A10 may include a gate electrode, a source electrode and a drain electrode, connected respectively to the scan lines, the data lines and the pixel electrode 10. Specifically, a through-hole may be defined to expose the drain electrode of the thin film transistor 20. The pixel electrode 10 may be electrically connected to the thin film transistor 20 through the through-hole.

It should be noticed that the pixel unit 10 may be controlled only by one thin film transistor 20.

The scan lines (G21, G22, G23, G24 . . . ) and the data lines (D21, D22, D23, D24, D25 . . . ) may cross each other. The scan lines may be arranged along one direction and output scan signal to the pixel units. One scan line may drive one row of pixel units. The data lines may be arranged along another direction. One data line may drive one column of pixel units.
Specifically, when powered on, the gate electrode of the thin film transistor 20 may be provided with a breakover voltage. The current may reach the source electrode through the data line, and then reach the drain electrode through the channel layer. Finally, the current may pass the through-hole to charge the pixel electrode.

When the pixel unit A10 is charged, the liquid crystal molecules may begin to incline along the direction of the branches. Since the directions of the branches of the main pixel portion and the secondary pixel portion are different, the inclination direction of the liquid crystal molecules corresponding to the main pixel portion may differ from that corresponding to the secondary pixel portion.

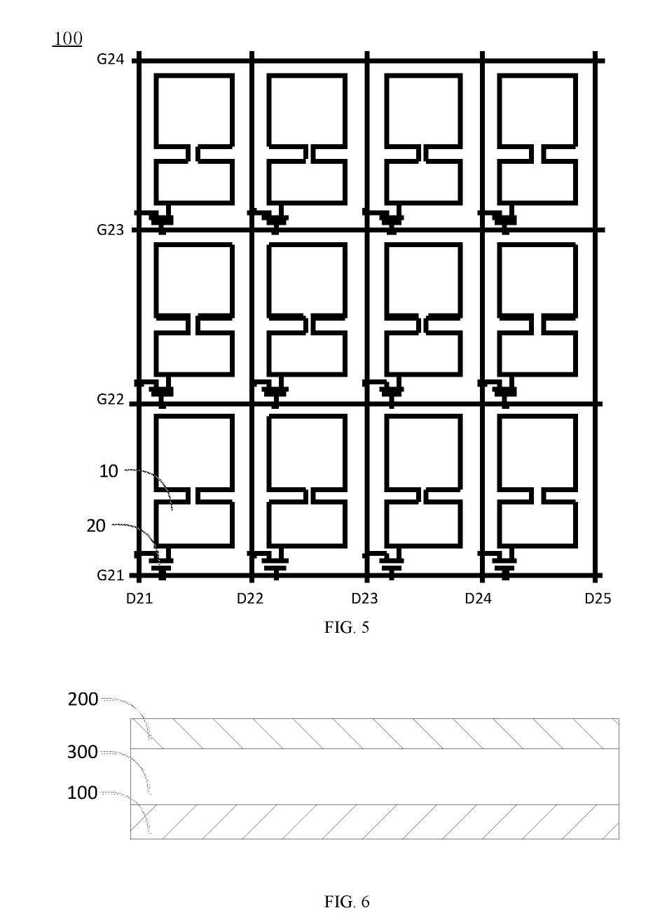

Referring to FIG. 6, FIG. 6 is a schematic diagram of a display panel according to an embodiment of the present disclosure.

The display panel may include an array substrate 100, an opposite substrate 200 arranged opposite to the array substrate 100 and a liquid crystal layer 300 therebetween. The array substrate 100 may include pixel units arranged as an array (not shown). The opposite substrate 200 may include a planar common electrode (not shown).

In one embodiment, the display panel may be a polymer stabilized vertically aligned (PSVA) display panel.

The array substrate 100 may be aligned with the opposite substrate 200. The liquid crystal layer 300 may be filled therebetween. The common electrode and the pixel unit array maybe charged such that the liquid crystal molecules may incline along a certain direction, i.e., the direction of the small slits patterned as shown in FIG. 2. Thus, in each of the pixel units, the liquid crystal molecules may have different inclination direction. When being irradiated by the ultraviolet ray, the monomer in the liquid crystal layer 300 may react and form the polymer protrusion attached on the pixel unit array and the common electrode. Correspondingly, the liquid crystal molecules in one pixel unit may have two different inclination direction.

In one embodiment, the display panel may be a vertical alignment (VA) display panel or a multi-domain vertical alignment (MVA) display panel.

The array substrate 100 may be aligned with the opposite substrate 200. The liquid crystal layer 300 may be filled therebetween. The common electrode and the pixel unit array maybe charged such that the liquid crystal molecules may incline along a certain direction, i.e., the direction of the small slits patterned as shown in FIG. 1. Thus, in each of the pixel units, the liquid crystal molecules may have different inclination direction.

The pixel unit, the array substrate and the display panel disclosed by the present disclosure may all include a main pixel portion and a secondary pixel portion electrically connected to the main pixel portion. The main pixel portion includes a first horizontal trunk, a first vertical trunk and first branches. The first vertical trunk is substantially perpendicular to and intersected with the first horizontal trunk. The first branches extend outward from the first horizontal trunk and the first vertical trunk, and located in a pixel domain defined by the first horizontal trunk and the first vertical trunk. The secondary pixel portion includes a second horizontal trunk, a second vertical trunk and a second branches. The second vertical trunk is substantially perpendicular to and intersected with the second horizontal trunk. The second branches extend outward from the second horizontal trunk and the second vertical trunk, and located in a pixel domain defined by the second horizontal trunk and the second vertical trunk. An acute angle between the first branches and the first horizontal trunk is different from an acute angle between the second branches and the second horizontal trunk. The implementation of the present disclosure may make the liquid crystal molecules in a pixel unit to have different inclination angle so as to improve the side viewing of the display panel.

The foregoing is merely embodiments of the present disclosure, and is not intended to limit the scope of the disclosure. Any transformation of equivalent structure or equivalent process which uses the specification and the accompanying drawings of the present disclosure, or directly or indirectly application in other related technical fields, are likewise included within the scope of the protection of the present disclosure.

1-20. (canceled)

21. A pixel electrode, comprising:
a main pixel unit portion and a secondary pixel unit portion, wherein
the main pixel unit portion comprises a first trunk, a second trunk substantially perpendicular to the first trunk, and a plurality of first branches extending outward from the first trunk and the second trunk, and symmetrically patterned about the first trunk portion and the second trunk portion, wherein a first acute angle between each of the first branches and the first trunk is substantially the same;
the secondary pixel unit portion comprises a third trunk, a fourth trunk substantially perpendicular to the third trunk, and a plurality of second branches extending outward from the third trunk and the fourth trunk, and symmetrically patterned about the third trunk portion and the fourth trunk portion, wherein a second acute angle between each of the second branches and the third trunk is substantially the same; and
the first acute angle is different from the second acute angle, and the second trunk is connected to the fourth trunk to enable the main pixel unit portion to be connected to the secondary pixel unit portion.

22. The pixel electrode of claim 21, further comprising an indium tin oxide structure, connecting the second trunk to the fourth trunk.

23. The pixel electrode of claim 21, wherein the main pixel unit portion and the secondary pixel unit portion are made of indium tin oxide.

24. The pixel electrode of claim 21, wherein
the first trunk, the second trunk and the first branches cooperatively define a first rectangular domain;
the third trunk, the fourth trunk and the second branches cooperatively define a second rectangular domain.

25. The pixel electrode of claim 24, wherein a ratio of a first area of the first rectangle domain to a second area of the second rectangle domain is between 3/7 and 7/3.

26. The pixel electrode of claim 21, wherein
the first acute angle is 45 degrees; and
the second acute angle is no less than 15 degrees and no more the 40 degrees, or, the second acute angle is no less than 50 degrees and no more than 75 degrees.

27. An array substrate, comprising a plurality of scan lines, a plurality of data lines, a plurality of pixel units formed at crossing points of the plurality of scan lines and the plurality of data lines, each of the plurality of pixel units comprising one thin film transistor and one patterned pixel electrode, wherein
the patterned pixel electrode comprises:
a main pixel unit portion, comprising a first trunk, a second trunk substantially perpendicular to the first trunk, and a plurality of first branches extending outward from the first trunk and the second trunk, and symmetrically patterned about the first trunk portion and the second trunk portion, wherein a first acute angle between each of the first branches and the first trunk is substantially the same; and
a secondary pixel unit portion, comprising a third trunk, a fourth trunk substantially perpendicular to the third trunk, and a plurality of second branches extending outward from the third trunk and the fourth trunk, and symmetrically patterned about the third trunk portion and the fourth trunk portion, wherein a second acute angle between each of the second branches and the third trunk is substantially the same; and
the first acute angle is different from the second acute angle, and the second trunk is connected to the fourth trunk to enable the main pixel unit portion to be connected to the secondary pixel unit portion;
the thin film transistor comprises a gate electrode connected to one of the plurality of scan lines, a source electrode connected to one of the plurality of data lines and a drain electrode connected to the patterned pixel electrode.

28. The array substrate of claim 27, wherein the patterned pixel electrode further comprises an indium tin oxide structure, connecting the second trunk to the fourth trunk.

29. The array substrate of claim 27, wherein the main pixel unit portion and the secondary pixel unit portion are made of indium tin oxide.

30. The array substrate of claim 27, wherein
the first trunk, the second trunk and the first branches cooperatively define a first rectangular domain;
the third trunk, the fourth trunk and the second branches cooperatively define a second rectangular domain.

31. The array substrate of claim 30, wherein a ratio of a first area of the first rectangle domain to a second area of the second rectangle domain is between 3/7 and 7/3.

32. The array substrate of claim 27, wherein
the first acute angle is 45 degrees; and
the second acute angle is no less than 15 degrees and no more the 40 degrees, or, the second acute angle is no less than 50 degrees and no more than 75 degrees.

33. A display panel, comprising an array substrate, an opposite substrate, and a liquid crystal layer between the array substrate and the opposite substrate, wherein
the array substrate comprises a plurality of scan lines, a plurality data lines, a plurality of pixel units formed at crossing points of the plurality of scan lines and the plurality of data lines, each of the plurality of pixel units comprises one thin film transistor and one patterned pixel electrode, wherein
the patterned pixel electrode comprises:
a main pixel unit portion, comprising a first trunk, a second trunk substantially perpendicular to the first trunk, and a plurality of first branches extending outward from the first trunk and the second trunk, and symmetrically patterned about the first trunk portion and the second trunk portion, wherein a first acute angle between each of the first branches and the first trunk is substantially the same; and
a secondary pixel unit portion, comprising a third trunk, a fourth trunk substantially perpendicular to the third trunk, and a plurality of second branches extending outward from the third trunk and the fourth trunk, and symmetrically patterned about the third trunk portion and the fourth trunk portion, wherein a second acute angle between each of the second branches and the third trunk is substantially the same and the first acute angle is different from the second acute angle and the second trunk is connected to the fourth trunk to enable the main pixel unit portion to be connected to the secondary pixel unit portion; and
the thin film transistor comprises a gate electrode connected to one of the plurality of scan lines, a source electrode connected to one of the plurality of data lines and a drain electrode connected to the patterned pixel electrode.

34. The display panel of claim 33, wherein the patterned pixel electrode further comprises an indium tin oxide structure, connecting the second trunk to the fourth trunk.

35. The display panel of claim 33, wherein the main pixel unit portion and the secondary pixel unit portion are made of indium tin oxide.

36. The display panel of claim 33, wherein
the first trunk, the second trunk and the first branches cooperatively define a first rectangular domain;
the third trunk, the fourth trunk and the second branches cooperatively define a second rectangular domain.

37. The display panel of claim 36, wherein a ratio of a first area of the first rectangle domain to a second area of the second rectangle domain is between 3/7 and 7/3.

38. The display panel of claim 33, wherein
the first acute angle is 45 degrees; and
the second acute angle is no less than 15 degrees and no more the 40 degrees, or, the second acute angle is no less than 50 degrees and no more than 75 degrees.
